(19) United States
(12) Patent Application Publication
(10) Pub. No.: US 2004/0256721 A1
(43) Pub. Date: Dec. 23, 2004

(54) Package for semiconductor devices

(75) Inventors: Luca Difalco, (US); Rosario Scollo, (US)

Correspondence Address: FLEIT, KAIN, GIBBONS, GUTMAN, BONGINI, & BIANCO P.L., ONE BOCA COMMERCE CENTER, 551 NORTHWEST 77TH STREET, SUITE 111, BOCA RATON, FL, 33487, US

(73) Assignee: STMICROELECTRONICS S.r.l., AGRATE BRIANZA (IT)

(21) Appl. No.: 10/765,454

(22) Filed: Jan. 27, 2004

(30) Foreign Application Priority Data
Jan. 27, 2003 (EP) 03425036.5

(51) Int. Cl. H01L 21/48; H01L 23/34

(52) U.S. Cl. 257/723; 438/109; 257/724

(57) ABSTRACT

A package for at least two semiconductor devices is provided. The package includes a first die including a first semiconductor device, a second die including a second semiconductor device, a DBC layer, and a third metal layer. The DBC layer includes a first metal layer, a second metal layer, and a ceramic material layer interposed between the first and second metal layers. The first metal layer of the DBC layer and the first die are attached to the third metal layer, and the second die is attached to the second metal layer of the DBC layer. In a preferred embodiment, the second semiconductor device is a MOS device (such as a MOS transistor) and the first semiconductor device is a bipolar device (such as a bipolar transistor).

### CROSS-REFERENCE TO RELATED APPLICATIONS

This application is based upon and claims priority from prior European Patent Application No. 03-425036.5, filed Jan. 27, 2003, the entire disclosure of which is herein incorporated by reference.

### BACKGROUND OF THE INVENTION

1. Field of the Invention

The present invention relates to packages for semiconductor devices, and more particularly to a package for at least two semiconductor devices.

2. Description of Related Art

Packages for semiconductor devices of the same type are generally known, for example for MOSFET or IGBT transistors or others. The packages typically includes one or more devices of the same type in accordance with the circuit topologies that a single package must comprise. However, in the case of a circuit topology comprising MOS and bipolar power transistors, a single package comprising both of them cannot be used. In fact for vertical power MOSFETs and for bipolar transistors with the collector terminal located on the bottom of the device, the use of a single package would be risking a short-circuit between the drain terminal and the collector terminal.

For example, in a cascode circuit topology comprising a bipolar transistor, particularly a high voltage power transistor, and a MOS transistor, particularly a low voltage power MOS transistor, a single package cannot be used that includes both of the above mentioned devices. Therefore, they are inserted in different packages and coupled outside the packages. A conventional cascode circuit is shown schematically in FIG. 1. The circuit comprises an n-channel MOS transistor M and an npn bipolar transistor Q. The MOS transistor M has the source terminal S connected to ground, the gate terminal G connected with a voltage Vim, and the drain terminal connected with the emitter terminal E of the bipolar transistor Q. The bipolar transistor Q has the base terminal connected with a voltage Vib through a base resistance Rb and the collector terminal C connected with a supply voltage Vcc. The conventional cascode circuit of FIG. 1 is formed by inserting two transistors inside different packages (which are indicated in FIG. 2 by the symbols W and Z) and by making the necessary external connections.

One technology used for packaging a semiconductor device is the DBC (Direct Bonding on Copper) technology. Such technology involves the soldering of a semiconductor device with a DBC layer formed by two copper layers with a ceramic material layer interposed between them. These DBC layers have better features of thermal resistance, electric insulation, mechanical severity, etc.

### SUMMARY OF THE INVENTION

It is an object of the present invention to provide an improved package for semiconductor devices.

Another object of the present invention to provide a package for at least two semiconductor devices.

One embodiment of the present invention provides a package for at least two semiconductor devices. The package includes a first die including a first semiconductor device, a second die including a second semiconductor device, a DBC layer, and a third metal layer. The DBC layer includes a first metal layer, a second metal layer, and a ceramic material layer interposed between the first and second metal layers. The first metal layer of the DBC layer and the first die are attached to the third metal layer, and the second die is attached to the second metal layer of the DBC layer. In a preferred embodiment, the second semiconductor device is a MOS device (such as a MOS transistor) and the first semiconductor device is a bipolar device (such as a bipolar transistor).

Another embodiment of the present invention provides a method for packaging at least two semiconductor devices in one package. According to the method, a first metal layer is provided, and a first die, which includes a first semiconductor device, is attached (e.g., via a solder layer) to the first metal layer. A DBC layer is attached (e.g., via a solder layer) to the first metal layer, and a second die, which includes a second semiconductor device, is attached (e.g., via a solder layer) to a third metal layer of the DBC layer. The DBC layer includes a second metal layer, the third metal layer, and a ceramic material layer interposed between the second and third metal layers.

Other objects, features, and advantages of the present invention will become apparent from the following detailed description. It should be understood, however, that the detailed description and specific examples, while indicating preferred embodiments of the present invention, are given by way of illustration only and various modifications may naturally be performed without deviating from the present invention.

### BRIEF DESCRIPTION OF THE DRAWINGS

FIG. 1 is a schematic diagram of a conventional cascode circuit;

FIG. 2 is a perspective view of the two packages that are conventionally used for the two transistors of FIG. 1;

FIG. 3 is a diagram of a package for two devices according to a preferred embodiment of the present invention before encapsulation;

FIG. 4 is a cross sectional view of the internal structure of the package of FIG. 3;

FIG. 5 is a perspective view of the package of FIG. 3 after encapsulation;

FIG. 6 is a perspective view of a package for two devices according to another embodiment of the present invention; and

FIG. 7 shows a graph of the collector current as a function of the collector-source voltage for the package of FIG. 3.

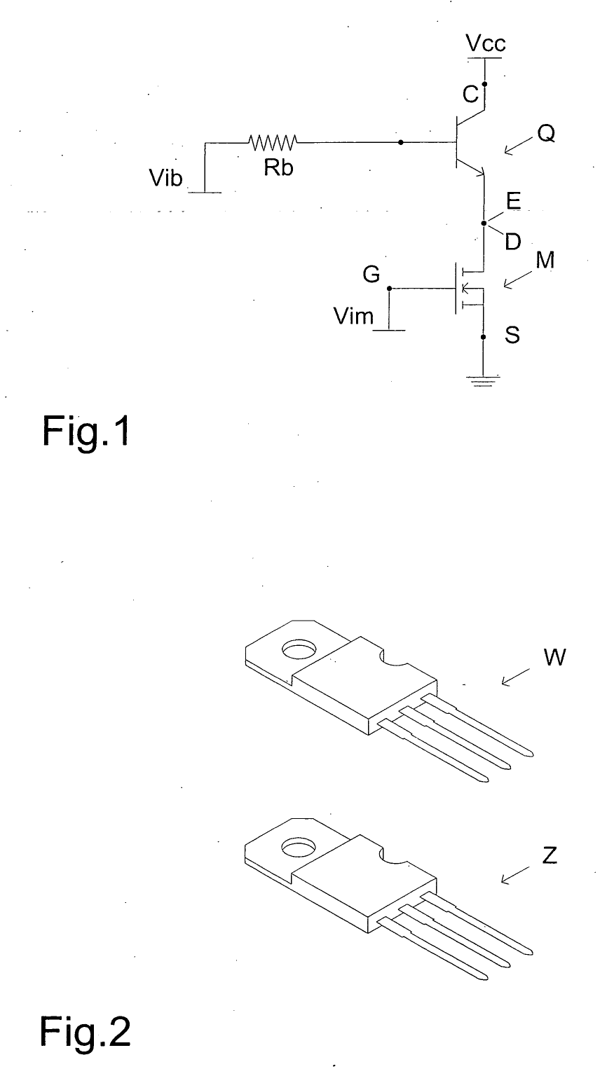

### DETAILED DESCRIPTION OF PREFERRED EMBODIMENTS

Preferred embodiments of the present invention will be described in detail hereinbelow with reference to the attached drawings.

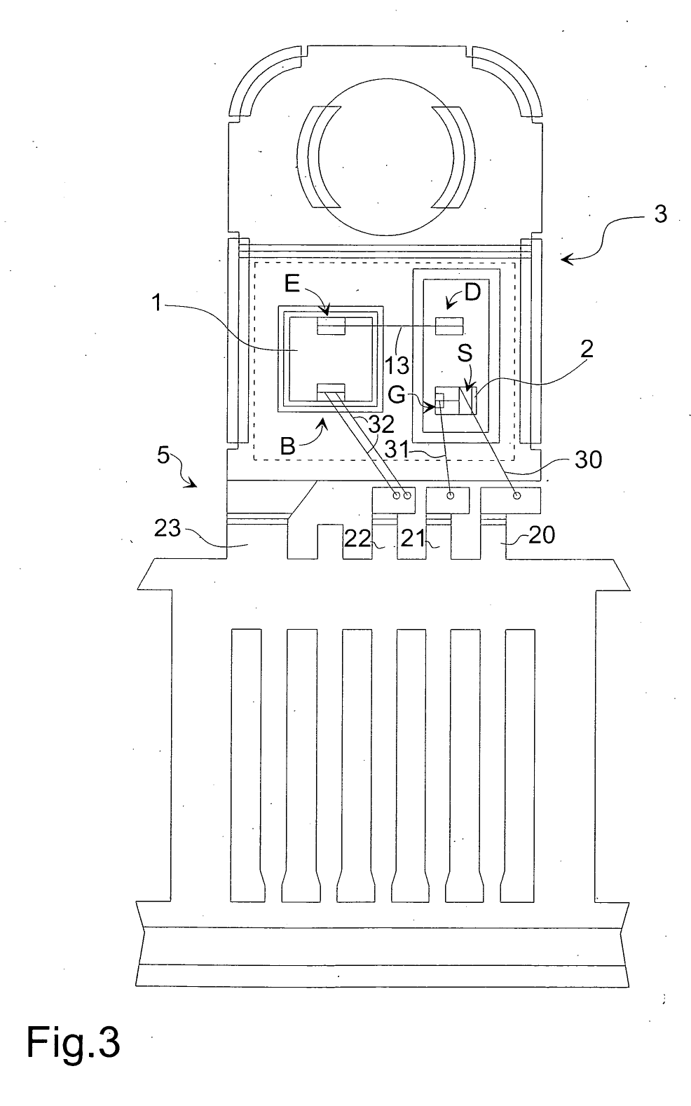

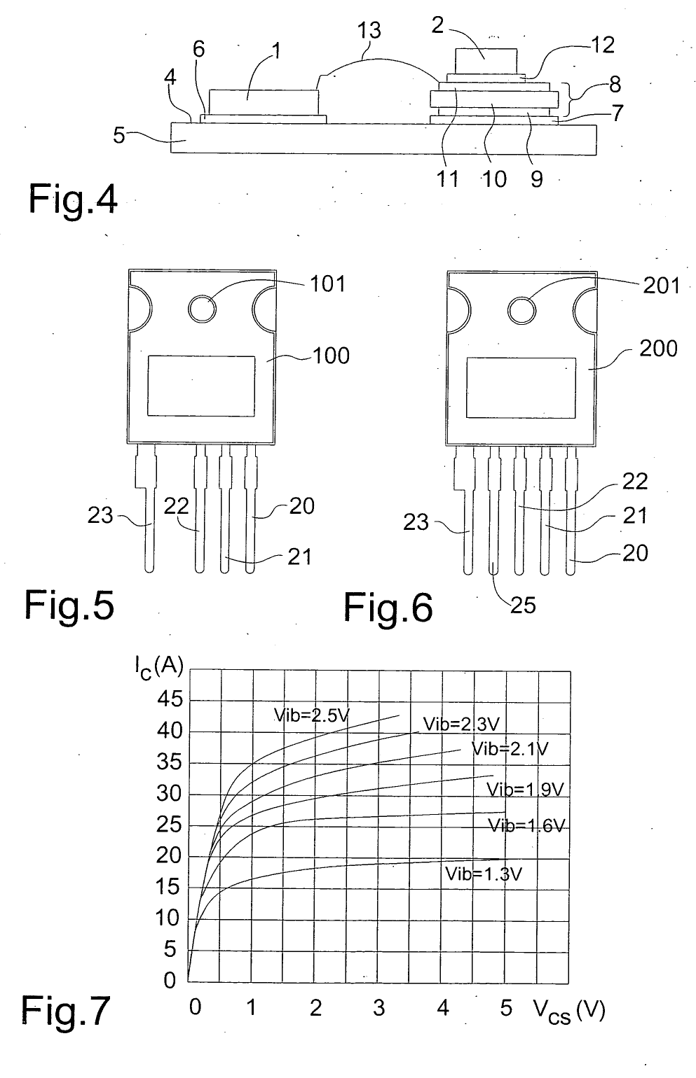

FIGS. 3-5 show the internal structure 3 of a package 100 for two semiconductor devices according to a preferred embodiment of the present invention. The two semiconductor devices are constituted by a bipolar transistor and a MOS transistor in this preferred embodiment, for example the two transistors forming the cascode circuit of FIG. 1. The die 1 of the bipolar transistor Q and the die 2 of the MOS transistor M are shown in FIGS. 3 and 4. The two dies 1 and 2 are allocated in the internal structure 3 of the package 100.

More precisely, as shown in FIG. 4, the die 1 of the bipolar transistor Q is attached directly over the top surface 4 of a conductor metal layer 5, generally called a leadframe, by a soldering layer 6. The metal layer 5 is placed on the bottom of the structure 3 and of the package 100.

On the same top surface 4 of the metal layer 5, in a zone away from the zone where the die 1 of the bipolar transistor Q is attached, a DBC layer 8 is attached by a further soldering layer 7. The DBC layer 8 comprises, in a bottom-up layer succession, a first copper layer 9, a ceramic material layer 10 (for example a layer of Al₂O₃), and a second copper layer 11. On the second copper layer 11, the die 2 of the MOS transistor M is soldered by another soldering layer 12.

A connection between the drain terminal D of the MOS transistor M and the emitter terminal E of the bipolar transistor Q is formed by a conductor wire 13, preferably of aluminum. The drain terminal D of the MOS transistor M is on the bottom of the die 2, and is therefore connected with the second copper layer 11 as shown in FIG. 4.

The leadframe 5 is suitably patterned for achieving the conductor terminals 20-23, called leads, of the structure 3 of the package 100 (FIG. 3). More precisely, the source S and gate G terminals of the MOS transistor M are connected by respective conductor wires 30 and 31 with the leads 20 and 21, respectively. The base terminal B of the bipolar transistor Q is connected with the lead 22 by further conductor wires 32; the leads 20-22 are not electrically connected to the metal layer 5. The collector terminal C of the bipolar transistor Q is located on the bottom of the die 1, and thus is directly connected with the leadframe 5 and is brought out of the internal structure 3 of the package 100 by the lead 23.

After cutting the leads 20-23 and encapsulating the structure 3, the package 100 is formed with pins corresponding to the leads 20-23 (FIG. 5). The package 100 has a hole 101 in this embodiment for connection with a suitable heatsink.

In another embodiment of the present invention, a package 200 is formed so as to have a further pin 25 which corresponds to a lead connected with the common terminal of the emitter E of the bipolar transistor Q and the drain D of the MOS transistor M, in order to control the current or the voltage on the common terminal (FIG. 6). The package 200 also has a hole 201 for connection with a suitable heatsink.

By using the package 100 or 200 for the cascode circuit structure of FIG. 1, all the external connections between the two transistors are eliminated and therefore the parasitic effects due to the external connections are removed. Also, a considerable cost reduction is obtained because a single package is used instead of the conventional two packages, and only four or five pins are used instead of the six pins of the two packages.

The use of a single package for both of the semiconductor devices with the bipolar transistor being insulated by a ceramic layer also allows the use of a single heatsink without the necessity of providing a ceramic layer between the package and the heatsink. The thermal resistance of the single package 100 is lower than the thermal resistance of the sum of the conventional two packages W and Z; this is due to the die 1 of the bipolar transistor Q attached to the leadframe 5 being in contact with the heatsink while the die 2 of the MOS transistor M is insulated.

In one illustrative example with a package 100 having a supply voltage Vcc=1000V, a collector current Ic=50 A, and an on-resistance Ron=25 mΩ, a total power dissipation of about 400 W is obtained at a temperature of 25° C. In another illustrative example with the values of Vcc=500V, Ic=30 A, a base resistance Rb=0.15 Ω, a gate-source voltage Vim=6V, a voltage Vib=2.5V, and with the source terminal connected to ground, the thermal resistance of the structure 3 of the package 100 is about 0.31° C./W, which by use of a heatsink is lowered to about 0.05° C./W. FIG. 7 shows a graph of the collector current Ic as a function of the collector-source voltage Vcs for different base voltages Vib, where Vim=6V and Rb=0.15 Ω.

While there has been illustrated and described what are presently considered to be the preferred embodiments of the present invention, it will be understood by those skilled in the art that various other modifications may be made, and equivalents may be substituted, without departing from the true scope of the present invention. Additionally, many modifications may be made to adapt a particular situation to the teachings of the present invention without departing from the central inventive concept described herein. Furthermore, an embodiment of the present invention may not include all of the features described above. Therefore, it is intended that the present invention not be limited to the particular embodiments disclosed, but that the invention include all embodiments falling within the scope of the appended claims.

What is claimed is:

1. A package for at least two semiconductor devices, the package comprising:
a first die including a first semiconductor device;
a second die including a second semiconductor device;
a DBC layer that includes a first metal layer, a second metal layer, and a ceramic material layer interposed between the first and second metal layers; and
a third metal layer to which the first metal layer of the DBC layer and the first die are attached,
wherein the second die is attached to the second metal layer of the DBC layer.

2. The package according to claim 1, wherein the second semiconductor device is a MOS device and the first semiconductor device is a bipolar device.

3. The package according to claim 2, wherein the bipolar device is a bipolar power transistor and the MOS device is a MOS power transistor, the bipolar transistor having a collector terminal directly electrically connected to the third metal layer.

4. The package according to claim 3, wherein the bipolar transistor is electrically coupled to the MOS transistor so as to form a cascode circuit.

5. The package according to claim 4, wherein the bipolar transistor has an emitter terminal electrically connected to a drain terminal of the MOS transistor.

6. The package according to claim 5, further comprising four pins, a first of the pins being electrically connected to a base terminal of the bipolar transistor, a second of the pins being electrically connected to the collector terminal of the bipolar transistor, a third of the pins being electrically connected to a source terminal of the MOS transistor, and a fourth of the pins being electrically connected to a gate terminal of the MOS transistor.

7. The package according to claim 6, further comprising a fifth pin for controlling a signal at the emitter terminal of the bipolar transistor.

8. The package according to claim 1, wherein the first semiconductor device is electrically coupled to the second semiconductor device.

9. An electronic system including a plurality of packages of semiconductor devices, at least one of the packages comprising:
a first die including a first semiconductor device;
a second die including a second semiconductor device;
a DBC layer that includes a first metal layer, a second metal layer, and a ceramic material layer interposed between the first and second metal layers; and
a third metal layer to which the first metal layer of the DBC layer and the first die are attached,
wherein the second die is attached to the second metal layer of the DBC layer.

10. The electronic system according to claim 9, wherein the second semiconductor device is a MOS device and the first semiconductor device is a bipolar device.

11. The electronic system according to claim 10, wherein the bipolar device is a bipolar power transistor and the MOS device is a MOS power transistor, the bipolar transistor having a collector terminal directly electrically connected to the third metal layer.

12. The electronic system according to claim 11, wherein the bipolar transistor has an emitter terminal electrically connected to a drain terminal of the MOS transistor.

13. The electronic system according to claim 12, wherein the at least one of the packages further comprises four pins, a first of the pins being electrically connected to a base terminal of the bipolar transistor, a second of the pins being electrically connected to the collector terminal of the bipolar transistor, a third of the pins being electrically connected to a source terminal of the MOS transistor, and a fourth of the pins being electrically connected to a gate terminal of the MOS transistor.

14. The electronic system according to claim 13, wherein the at least one of the packages further comprises a fifth pin for controlling a signal at the emitter terminal of the bipolar transistor.

15. The electronic system according to claim 9, wherein the first semiconductor device is electrically coupled to the second semiconductor device.

16. A method for packaging at least two semiconductor devices in one package, the method comprising the steps of:
providing a first metal layer;
attaching a first die, which includes a first semiconductor device, to the first metal layer;
attaching a DBC layer to the first metal layer, the DBC layer including a second metal layer, a third metal layer, and a ceramic material layer interposed between the second and third metal layers; and
attaching a second die, which includes a second semiconductor device, to the third metal layer of the DBC layer.

17. The method according to claim 16, wherein the second semiconductor device is a MOS transistor and the first semiconductor device is a bipolar transistor.

18. The method according to claim 17, wherein in the step of attaching the first die, a collector terminal of the bipolar transistor is directly electrically connected to the first metal layer.

19. The method according to claim 18, further comprising the step of electrically connecting an emitter terminal of the bipolar transistor to a drain terminal of the MOS transistor.

20. The method according to claim 19, further comprising the steps of:
electrically connecting a first pin to a base terminal of the bipolar transistor;
electrically connecting a second pin to the collector terminal of the bipolar transistor;
electrically connecting a third pin to a source terminal of the MOS transistor; and
electrically connecting a fourth pin to a gate terminal of the MOS transistor.

21. The method according to claim 16, wherein the first semiconductor device is electrically coupled to the second semiconductor device.
